(19) United States
(12) Patent Application Publication
(10) Pub. No.: US 2023/0104691 A1
(43) Pub. Date: Apr. 6, 2023

(54) INTRACAVITY PUMPED PASSIVELY Q-SWITCHED LASER

(71) Applicants: Thomas James Kane, Menlo Park, CA (US); John Lawrence Nightingale, Portola Valley, CA (US)

(72) Inventors: Thomas James Kane, Menlo Park, CA (US); John Lawrence Nightingale, Portola Valley, CA (US)

(21) Appl. No.: 17/958,368

(22) Filed: Oct. 1, 2022

Related U.S. Application Data
(60) Provisional application No. 63/251,590, filed on Oct. 2, 2021.

(51) Int. Cl. H01S 5/06; H01S 5/00; H01S 5/026; H01S 5/04; H01S 5/10; H01S 5/183

(52) U.S. Cl. CPC H01S 5/0615; H01S 5/0071; H01S 5/0261; H01S 5/041; H01S 5/1025; H01S 5/18361; G01S 7/4865

(57) ABSTRACT

A passively Q-switched laser with intracavity pumping is described. The passively Q-switched laser has an optically pumped gain element and a saturable absorber element. The optically pumped gain element is situated in an extended cavity of a VECSEL (Vertical Extended Cavity Surface Emitting Laser) so that the gain element is pumped by a circulating pump beam of the VECSEL. The passively Q-switched laser may produce output pulses at an eye-safe wavelength using a low gain laser transition and may use a plurality of surface emitting gain regions to pump the passively Q-switched laser.

### CROSS REFERENCE TO RELATED APPLICATIONS

This application claims priority to U.S. Provisional Patent Application Ser. No. 63/251,590, entitled “INTRACAVITY PUMPED PASSIVELY Q-SWITCHED LASER”, filed Oct. 2, 2021 which is incorporated herein in its entirety for all purposes.

### FIELD OF THE INVENTION

The present invention relates to systems and methods of positioning a gain element of a passively Q-switched laser within a second laser cavity so that the gain element is pumped by the circulating power of the second laser.

### BACKGROUND

Passively Q-switched lasers utilize a saturable absorber in a laser cavity to generate Q-switched pulses. Switching occurs when gain in a gain element is sufficient to overcome a small-signal loss in the saturable absorber. The saturable absorber is then bleached, and the stored gain is emitted as a laser pulse. An advantage of passively Q-switched lasers is their simplicity, since no high-speed electronics are required to generate laser pulses with pulse energies exceeding 1 kW.

A passively Q-switched laser resonator may be formed by integrating resonator mirrors on the end faces of the gain element and the saturable absorber. A high reflecting mirror may be placed on an outer surface of the gain element and an output coupler on an outer surface of the saturable absorber. In the prior art, the laser resonator is typically end-pumped by a semiconductor laser. A pump beam emitted by the semiconductor laser is transmitted through the high reflecting mirror into the gain element, where it is absorbed. A focusing lens is typically placed between the gain element and the pump laser to control a pump beam size in the gain element. Laser resonator stability may be obtained by thermal lensing in the gain element and/or deformation of the resonator end faces to form a stable laser cavity.

The arrangement described above is a simple and low-cost method for generating optical pulses with high peak power; however, it has several limitations. One limitation is that the pump beam must be at a wavelength that is strongly absorbed in the gain element. Since an output wavelength of a semiconductor laser varies with operating temperature, the semiconductor laser is often temperature controlled with a concomitant increase in system cost and complexity. A second limitation is that the passively Q-switched laser works best with very bright pump lasers, such as an edge-emitting laser diode. Surface emitting lasers are cheaper to manufacture than edge emitting laser diodes but have lower brightness, which reduces their utility in pumping a passively Q-switched laser.

What is needed is a simple system and method to use a surface emitting semiconductor light source to pump a passively Q-switched laser.

### SUMMARY

In one embodiment, a passively Q-switched laser configured to operate at a first wavelength is described. The passively Q-switched laser includes an optically pumped gain element absorptive at a second wavelength and a saturable absorber element. The optically pumped gain element and the saturable absorber element are disposed within a first resonator configured to oscillate at the first wavelength. A plurality of electrically pumped surface emitting semiconductor gain regions are configured to lase at the second wavelength forming a circulating pump beam between at least one of the plurality of electrically pumped surface emitting semiconductor gain regions and an external optical element. The optically pumped gain element is disposed within the circulating pump beam.

In another embodiment, a passively Q-switched laser configured to operate at a first wavelength is described. The passively Q-switched laser includes an optically pumped gain element absorptive at a second wavelength and a saturable absorber element. The optically pumped gain element and the saturable absorber element are disposed within a first resonator configured to oscillate at the first wavelength. Two electrically pumped surface emitting semiconductor gain regions in optical communication with each other are configured to lase at the second wavelength forming a circulating pump beam. The optically pumped gain element is disposed within the circulating pump beam.

In another embodiment, a passively Q-switched laser configured to output an pulsed laser beam is described. The passively Q-switched laser is comprised of a vertical extended cavity surface emitting laser (VECSEL). The VECSEL is configured to generate a circulating pump beam at a VECSEL lasing wavelength in the extended cavity. Disposed within the extended cavity is an optically pumped gain element having a first gain element surface and a second gain element surface. An optical path of the circulating pump beam extends at least between the first gain element surface and the second gain element surface. The optically pumped gain element has a high gain laser transition and a low gain laser transition. The passively Q-switched laser further includes a high reflectivity coating at a Q-switched lasing wavelength forming a first end of a Q-switched resonator and an output coupler at the Q-switched lasing wavelength forming a second end of the Q-switched resonator. The passively Q-switched laser further includes a saturable absorber element disposed in the Q-switched resonator. The Q-switched lasing wavelength is generated by the low gain laser transition and is an eye-safe wavelength.

### BRIEF DESCRIPTION OF THE DRAWINGS

The invention and the advantages thereof, may best be understood by reference to the following description taken in conjunction with the accompanying drawings in which:

FIG. 1 is a schematic cross-sectional diagram of a prior art Vertical Extended Cavity Surface Emitting Laser (VECSEL) with a nonlinear crystal positioned in an extended cavity of the VECSEL.

FIG. 2 is a schematic cross-sectional diagram of a VECSEL with a gain element of a passively Q-switched laser in an extended cavity of the VECSEL according to an embodiment of the present invention.

FIG. 3 is a perspective view of a 1-dimensional array of intracavity pumped passively Q-switched lasers according to an embodiment of the present invention.

FIG. 4A is a schematic cross-sectional diagram of a VECSEL with an optically pumped gain element of a passively Q-switched laser in an extended cavity of the VECSEL having two surface emitting semiconductor gain regions according to an embodiment of the present invention.

FIG. 4B is a schematic top view of the passively Q-switched laser depicted in FIG. 4A according to an embodiment of the present invention.

FIG. 5 is a schematic side view of a plurality of surface emitting semiconductor gain regions pumping a single passively Q-switched laser according to an embodiment of the present invention.

FIG. 6 is a schematic side view two opposed sets of a plurality of surface emitting semiconductor gain regions pumping a single passively Q-switched laser according to an embodiment of the present invention.

In the drawings, like reference numerals are sometimes used to designate like structural elements. It should also be appreciated that the depictions in the figures are diagrammatic and not to scale.

### DETAILED DESCRIPTION

The present invention relates to methods and systems for pumping a passively Q-switched laser with a surface emitting semiconductor light source. One particularly attractive application for the passively Q-switched laser is laser ranging, commonly known as LIDAR. In this application, the laser may be a passively Q-switched laser operating at an eye-safe wavelength. Eye-safe wavelengths may be considered as wavelengths longer than approximately 1.2 microns and particularly wavelengths between 1.2 and 1.4 microns. Inclusion of a saturable absorber element within the laser cavity causes the laser to passively Q-switch, resulting in a pulsed output with high peak powers, which is useful in time-of-flight ranging applications. Passively Q-switched lasers operating at a wavelength of approximately 1.34 microns may use a saturable absorber based on vanadium ions in a crystalline or glass host material. The gain material may be neodymium ions doped in a crystalline or glass host matrix. The host matrix may be an electrical insulator so that the gain material must be optically pumped.

Unlike most prior art passively Q-switched lasers, the present invention places a gain element of the passively Q-switched laser inside the laser cavity of a second laser. A portion of the circulating power within the second laser's resonant cavity is absorbed by the gain element of the passively Q-switched laser, pumping the passively Q-switched laser. Such an arrangement may be referred to as intracavity pumping, since the passively Q-switched laser gain element is internal to the cavity of the second laser. Intracavity pumping enables efficient pumping without requiring the second laser wavelength to be overlapped with a strong absorption feature of the gain element of the passively Q-switched laser. The second laser may be a surface emitting semiconductor light source, such as a VECSEL (Vertical Extended Cavity Surface Emitting Laser) or an edge emitting semiconductor laser.

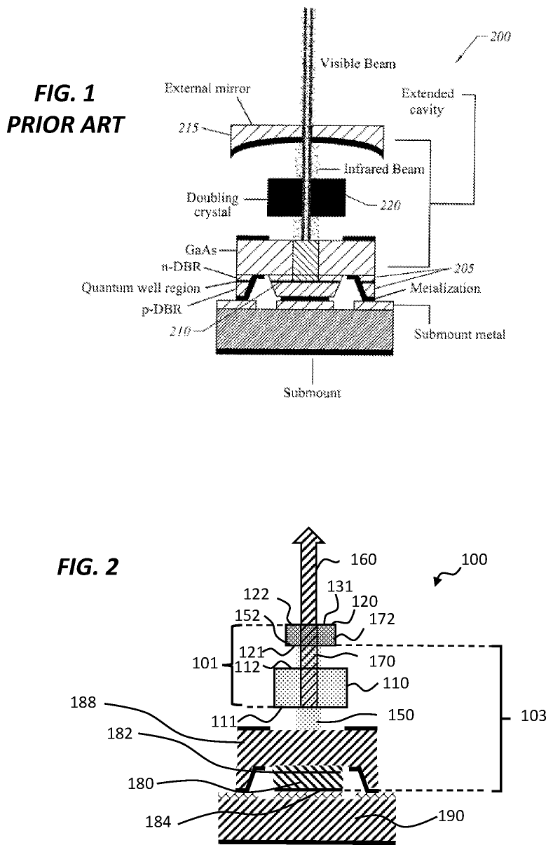

FIG. 1 depicts a cross-section of a prior art VECSEL 200 disclosed in U.S. Pat. No. 7,359,420. Extended cavity surface-emitting semiconductor lasers are a class of semiconductor lasers that have a number of advantages over edge emitting semiconductor lasers or conventional surface emitting lasers commonly known as VCSELs (Vertical Cavity Surface Emitting Lasers). Extended cavity surface emitting lasers includes at least one reflector disposed adjacent and monolithically integrated with a surface emitting semiconductor gain region. A a pair of distributed Bragg reflectors (DBRs) 205, a p-type DBR and a n-type DBR, is epaxially grown on either side of a plurality of quantum wells that form a surface emitting semiconductor gain region 210. The two reflectors form a Fabry-Perot cavity; however, the n-type DBR has fewer layers than the p-type DBR and thus has a lower reflectivity. The reflectivity of the n-type DBR is too low to support lasing in the Fabry-Perot cavity without additional feedback. Said another way, the gain region 210 has insufficient gain to overcome the cavity losses to support lasing without some additional feedback. The additional feedback is provided by an external reflector 215 spaced apart from the surface emitting semiconductor gain region that defines an extended cavity of the VECSEL 200. The external reflector 215 can provide wavelength control and transverse mode control of resonant light circulating within the extended cavity. By appropriate selection of the quantum well gain region 210, DBRs 205, and external reflector 215 a VECSEL lasing wavelength can be selected within a large range of wavelengths. In the prior art VECSEL 200, the lasing wavelength is frequency doubled by a frequency doubling optical crystal 220 to generate light at a desired color.

FIG. 2 depicts an intracavity pumped, passively Q-switched laser 100 according to an embodiment of the present invention. The passively Q-switched laser 100 may be pumped by a semiconductor die 188 mounted to a submount or heat sink 190. The passively Q-switched laser 100 may have two nested laser resonators, a VECSEL resonator 103 and a passively Q-switched laser resonator 101. The VESCEL resonator 103 may lase at a pump wavelength of the passively Q-switched laser resonator 101. The VECSEL resonator 103 may include a surface emitting semiconductor gain region 180 positioned between reflectors 182 and 184 all of which are monolithically integrated in the semiconductor die 188, which may be similar to the surface emitting semiconductor gain region of the prior art. The reflector 184 may be a high reflector that forms one end of the VECSEL resonator 103. A second end of the VECSEL resonator may be formed by an external optical element 172. Two elements may form the passively Q-switched laser resonator 101, an optically pumped gain element 110 and a saturable absorber element 120. In the exemplary embodiment depicted in FIG. 2 the saturable absorber element 120 also serves as the external optical element 172, but this is not a requirement.

Optical coatings may be applied to optical surfaces of the optically pumped gain element 110. A first surface 111, which forms one end of the passively Q-switched laser resonator 101, may be coated for high transmission at the pump wavelength, and for high reflection at a lasing wavelength of the passively Q-switched laser. A second surface 112, opposing the first surface 111, may be coated for high transmission at the passively Q-switched laser wavelength and the pump wavelength. A partially transmitting optical coating 131 may be applied to a second surface 122 of the saturable absorber 120 to form an output coupler that serves as an end mirror for the passively Q-switched resonator 101. The first surface 121 of the saturable absorber may be anti-reflection coated at the passively Q-switched laser wavelength and may be coated to be a high reflector at the pump wavelength. The first surface 121 of the saturable absorber 120 may thus serve as an external mirror 152 for the VECSEL resonator 103. Alternatively, the external mirror 152 for the VECSEL resonator may be formed on the second surface 112 of the optically pumped gain element 110 or the second surface 122 of the saturable absorber element 120.

In some embodiments, all the optical surfaces 111, 112, 121, and 122 may be flat, that is they may have no deliberately fabricated curvature. Curvature of one or more of these surfaces may be induced by application of an optical coating to the surface or by thermal effects when the passively Q-switched resonator 101 is energized by circulating pump light 150 generated by the quantum well region of the VECSEL resonator 103. Alternatively, one or more of the optical surfaces 111, 112, 121, and 122 may be deliberately curved to help control the transverse mode structure of either or both the VECSEL resonator 103 and the passively Q-switched laser resonator 101. All other surfaces of the optically pumped gain element 110 and saturable absorber element 120 may be non-optical surfaces, which are not arranged to transmit light. These non-optical surfaces may also be flat, but they do not need to be optically polished.

Both the optically pumped gain element 110 and the saturable absorber element 120 may be shaped as a rectangular parallelopiped. The optically pumped gain element 110 may be a neodymium doped YVO₄ or yttrium aluminum garnet (YAG) crystal and the saturable absorber element 120 may be a vanadium doped YAG crystal. The lasing wavelength may be approximately 1.34 microns. The optically pumped gain element 110 and saturable absorber element 120 must be aligned so that the resonant light 170 reflects off the two end mirror coatings and returns to the same point. The desired condition of a ray reflecting back on itself indefinitely may be achieved by adjusting the alignment of the optically pumped gain element 110 to the saturable absorber 120 to angularly align the second surface 122 of the saturable absorber element 120 with the first surface 111 of the optically pumped gain element 110.

In some embodiments, there may a gap between the optically pumped gain element 110 and the saturable absorber element 120 as shown in FIG. 2. In other embodiments, the optically pumped gain element 110 and the saturable absorber element 120 may directly contact each other, such that there is no gap between these elements. If there is no gap, the second surface 112 of the gain element 110 and first surface 121 of the saturable absorber element 120 may be uncoated and the surfaces may be optically contacted to each other.

When the intensity of the pump light 150 is sufficient so that the optically pumped gain element 110 has sufficient gain to overcome any losses within the passively Q-switched laser resonator 101, the intracavity pumped, passively Q-switched laser 100 will lase. Resonant light 170 will circulate between the first surface 111 of the optically pumped gain element 110 and the second surface 122 of the saturable absorber 120 at the laser wavelength of the passively Q-switched laser 100, which may be denoted as a first wavelength. A fraction of the resonant light 170 will emerge through the partially transmitting optical coating 131 to form the output beam 160. The optical coatings may be arranged so that the output beam 160 is at a laser wavelength of approximately 1.34 microns.

The optical surfaces 111 and 112 of the optically pumped gain element 110 may optionally be coated to control a lasing wavelength of the VECSEL resonator, which provides the pump light 150. The pump light may be denoted as having a second wavelength, which is different than the first wavelength of the passively Q-switched laser. The optical surfaces 111 and 112 may have a narrow transmission window at a pump wavelength for the optically pumped gain element 110 to suppress lasing of the VECSEL resonator 103 at wavelengths which would be ineffective in pumping the gain element 110. The pump light wavelength may be within the range of approximately 750 nm to 950 nm where a neodymium doped YVO₄ or YAG crystal has various absorption peaks. For other optically pumped gain materials, such as ytterbium, praseodymium, holmium, thulium, or erbium doped YAG or some other glass or crystal host the pump light wavelength may be outside of this wavelength range.

In operation, current may be applied to the gain region of the VECSEL resonator 103. The applied current causes the gain region to produce photons, a fraction of which are reflected back into the gain region by the external mirror 152. The VECSEL resonator 103 will lase when the optical gain in the gain region is greater than all the optical losses in the VECSEL resonator 103. Lasing of the VECSEL resonator 103 will generate a circulating pump beam 150 in the extended cavity of the VECSEL at a pumping wavelength for the optically pumped gain element 110. A portion of the circulating pump beam 150 in the extended cavity will be absorbed in the optically pumped gain element 110. Absorption in the optically pumped gain element 110 will generate optical gain at a lasing wavelength of the passively Q-switched laser resonator 101. As such, light at the Q-switched lasing or first wavelength will be amplified as it passes through the optically pumped gain element 110. The passively Q-switched laser resonator 101 will lase when the optical gain in the optically pumped gain element 110 is greater than the optical losses in the passively Q-switched laser resonator 101. The passively Q-switched laser 100 may produce output pulses with a substantially constant pulse energy and pulse width. The pulse repetition rate may be varied by adjusting a current applied to the gain region of the VECSEL.

An advantage of the intracavity pumped, passively Q-switched laser 100 is that the single pass absorption of the pump light 150 may be relatively low since the pump light 150 may be recirculated through the optically pumped gain element 110 multiple times. This allows pumping with a broader range of pump wavelengths than with a prior art end-pumped passively Q-switched laser. For example, the single pass absorption at the pumping wavelength may be only 20%, 10% or less, which would be prohibitively low for an end-pumped laser. This allows the optically pumped gain element 110 to be very thin or have a lower doping level of neodymium or some other lasing dopant.

In other embodiments, various other elements may be included in the extended cavity of the VECSEL resonator 103. These elements may include, but are not limited to, a polarization control element, such as a tilted window that has differential transmission for light of different polarizations, a wavelength control element, such as a volume Bragg grating, a notch filter or an etalon that serves as a spectral filter, or a transverse mode control element, such as a lens or aperture.

To increase the output power of a passively Q-switched laser system a plurality of surface emitting semiconductor gain regions may be used. At least two of the plurality of surface emitting semiconductor gain regions may be monolithically fabricated on a single semiconductor die. These surface emitting semiconductor gain regions may be arranged in a serial or parallel manner. In alternative embodiments, each semiconductor die may have only a single surface emitting semiconductor gain region.

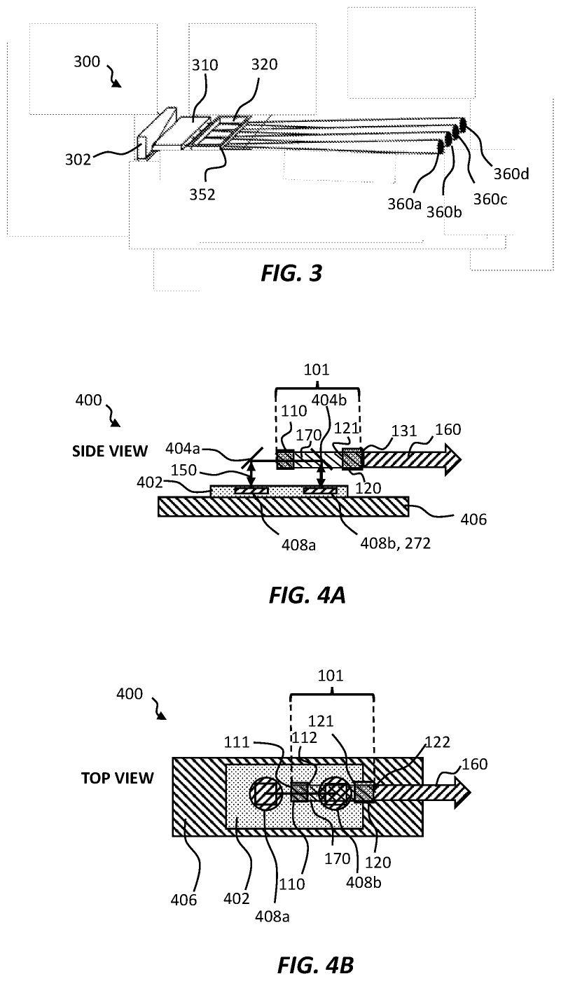

In a parallel embodiment, each surface emitting semiconductor gain region may be associated with a single VECSEL resonator 103. The optically pumped gain element 110 and saturable absorber element 120 may be common to a plurality of VECSEL resonators. FIG. 3 is a perspective view of a parallel arrangement showing a 1-dimensional array of intracavity pumped passively Q-switched lasers 300. The laser array 300 may be energized by a plurality of surface emitting semiconductor gain regions on a monolithic semiconductor substrate 302. There are four surface emitting semiconductor gain regions on the exemplary semiconductor substrate 302 depicted in FIG. 3; however, the gain regions are not visible in FIG. 3. Each of the four surface emitting semiconductor gain regions may direct pump light into an optically pumped gain element 310. A saturable absorber element 320 causes Q-switching. A surface of the saturable absorber element 320 may serve as the external mirror 352 for the surface emitting semiconductor gain regions. Alternatively, a separate external mirror may be used. Four output beams 360a-360d are generated. While four VECSELs are shown in FIG. 3, the invention is not so limited. Many VECSELs, such as 5, 10, 20, 50, 100, 200, 500 or any number between these values may be fabricated using a single semiconductor substrate 302. The surface emitting semiconductor gain regions may be arranged in a 1-dimensional array as shown in FIG. 3 or a 2-dimensional array. As shown in FIG. 3 a single piece of optically pumped gain element 310 and saturable absorber element 320 may be used to form a plurality of passively Q-switched lasers.

In a serial embodiment, a plurality of surface emitting semiconductor gain regions are configured to pump a single VECSEL resonator. An example of an intracavity pumped, passively Q-switched laser 400 using such a VECSEL resonator is shown in FIGS. 4A and 4B, which show a side and top view, respectively. The surface emitting semiconductor gain regions 408a and 408b may be fabricated on a monolithic semiconductor substrate 402. The semiconductor substrate 402 may be mounted on a heat sink or submount 406. Unlike the embodiment depicted in FIG. 2, the VECSEL laser resonator is not linear, but includes two cavity turning mirrors 404a and 404b. Both cavity turning mirrors 404a and 404b may be dichroic mirrors with high reflectivity at the pump wavelength, which is the wavelength of the circulating light 150 in the VECSEL cavity. Cavity turning mirror 404b may additionally have an anti-reflection (AR) coating for the lasing wavelength of the passively Q-switched laser resonator 101. The cavity turning mirrors 404a and 404b place the two surface emitting semiconductor gain elements 408a and 408b in optical communication which each other so they can exchange optical energy at the pumping or second wavelength. Both ends of the VECSEL cavity are defined by the surface emitting semiconductor gain regions 408a and 408b. In this embodiment, the surface emitting semiconductor gain region 408b may be considered to be an external optical element 272 that is in optical communication with the surface emitting semiconductor gain region 408a to form the VECSEL resonator.

An advantage of this embodiment is that the output of two surface emitting semiconductor gain regions 408a and 408b may be incorporated into a single VECSEL cavity, increasing a circulating power in the VECSEL cavity beyond that which may be achieved with a single surface emitting semiconductor gain region. This may allow the output beam 160 of the passively Q-switched laser to have a higher average power than the output beam achievable with a single surface emitting semiconductor gain region.

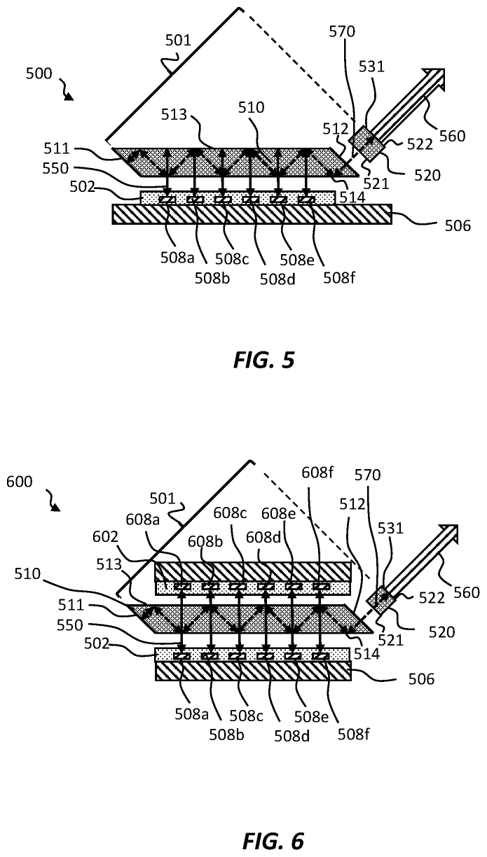

Another serial embodiment having a plurality of surface emitting semiconductor gain elements providing gain to a single passively Q-switched laser 500 is depicted in FIG. 5. In this embodiment, a gain element 510 may be shaped as a parallelopiped having four rectangular faces and two faces being non-rectangular parallelopipeds. The four rectangular faces may be denoted as a first end face 511, a second end face 512, an opposed lateral face 513, and an adjacent lateral face 514. An angle between the first end face 511 and adjacent lateral face 513 may be either an acute or obtuse angle. In the exemplary embodiment depicted in the FIG. 5 the angle is 45°. The four rectangular faces may all be optically polished. The other faces of the gain element 510 may have a non-optical surface finish. A saturable absorber element 520 may be a shaped as rectangular parallelopiped. The saturable absorber element may have a first end face 521 and a second end face 522 that are both optically polished. The other faces of the saturable absorber element 520 may have a non-optical surface finish.

The gain element 510 may be configured to be optically pumped and may be described as an optically pumped gain element. The first end face 511 of the gain element 510 and the second end face 522 of the saturable absorber element 520 may form a passively Q-switched resonator 501. The first end face 511 of the gain element 510 may be a high reflector at a first wavelength, the first wavelength being a lasing wavelength of the passively Q-switched laser 500. The second end surface 522 of the saturable absorber 520 may form an output coupler 531 for the lasing wavelength of the passively Q-switched laser 500. Within the passively Q-switched resonator 501 resonant light 570 may circulate back and forth between the first end face 511 of the gain element 510 and the second end face 522 of the saturable absorber element 520. The resonant light 570 may follow a zig-zag optical path through the gain element 510. That is the resonant light 570 may reflect off one or preferably both of the lateral faces 513 and 514 of the gain element 510. Such a laser geometry may be referred to as a slab laser. The reflection may be achieved either through total internal reflection or through a multi-layer dielectric coating applied to the lateral faces 513 and 514 of the gain element 510. There may be any number of reflections between the first end face 511 and the second end face 512 of the gain element 510. Eight reflections or bounces in the zig-zag pattern are shown in FIG. 5, but more or fewer reflections may be used. An advantage of using a zig-zag optical path through the resonator 501 is that the resonant light 570 can extract gain from pump regions directly adjacent the lateral faces 513 and 514.

Disposed adjacent the adjacent lateral faces 514 of the gain element 510 may be a semiconductor gain element 502. The semiconductor gain element 502 may be formed on a monolithic substrate and may be mounted to a submount or heat sink 506. The semiconductor gain element may contain a plurality of semiconductor gain regions 508a-508f. The semiconductor gain regions 508a-508f may be situated between reflectors and both the gain regions and reflectors (not shown in FIG. 5) may be formed using a plurality of epitaxially grown layers of different semiconductor materials and photolithographic techniques. Each semiconductor gain region 508a-508f may be characterized as a surface emitting gain region since light emitted from the gain regions 508a-508f is generally directed perpendicular to the epitaxially grown layer. Without feedback or light from an external optical element, the surface emitting semiconductor gain regions 508a-508f may have insufficient gain to lase when pumped by injecting electrical current into the surface emitting semiconductor gain regions. Application of external feedback or light from the external optical element to the surface emitting semiconductor gain regions 508a-508f may cause the gain regions to lase. The external feedback may be a reflection from the opposed lateral face 513 of the optically pumped gain element 510, which is the lateral face situated farthest from the surface emitting semiconductor gain element 502. Thus, in the embodiment depicted in FIG. 5 the external optical element is the optically pumped gain element 510. The external feedback may be sufficient to cause each surface emitting semiconductor gain region 508a-508f to lase resulting in a circulating pump beam 550 at a second wavelength circulating between the surface emitting semiconductor gain regions 508a-508f and the opposed lateral face 513. The second wavelength of the circulating pump light 550 may be at a shorter wavelength than the first wavelength at which the passively Q-switched laser 500 lases. As shown in FIG. 5 the reflection points of the resonant light 570 may be aligned with the surface emitting semiconductor gain regions 508a-508f although this is not a requirement. An advantage of the alignment is that it may provide better mode overlap of the resonant light 570 with the circulating pump beams 550.

Application of sufficient current to the surface emitting semiconductor gain regions 508a-508f will result in lasing of some or all of the gain regions. The surface emitting semiconductor gain regions 508a-508f may all act independently or there may be some optical coupling between the gain regions. Some of the circulating pump light 550 at the second wavelength is absorbed in the optically pumped gain element 510 resulting in gain at the first wavelength. When the gain is sufficient to overcome the saturable loss induced by the saturable absorber element 520, the passively Q-switched laser 500 will emit a pulsed output beam 560 through an output coupler 531. Thermal lensing may stabilize a transverse mode of the lasing passively Q-switched laser 500. Alternatively, any of the gain element end faces 511 and 512 or saturable absorber element end faces 521 and 522 may be curved. In yet another alternative, either or both of the gain element first end face 511 or saturable absorber element 522 may be anti-reflection coated at the first lasing wavelength. An end of the resonator 501 may then be formed on an external optical element positioned adjacent either the gain element first end face 511 or the saturable absorber element second end face 522. An aperture may also be placed in the resonator 501 to provide transverse mode control and help facilitate single transverse mode operation.

An advantage of the embodiment depicted in FIG. 5 is that many surface emitting semiconductor gain regions 508a-508f may be used to pump a single passively Q-switched laser. This may allow for significantly higher output powers, pulse repetition rates, and pulse energies that those achievable using only a single surface emitting semiconductor gain region as a pump source. A further advantage of the embodiment is that the output beam 560 may have a near-diffraction limited beam quality, for example, an M² value less than 1.5. This contrasts with the embodiment depicted in FIG. 3 where although each output beam 360a-360d may have a near-diffraction limited beam quality, the beam quality of the collection of output beams 360a-360d is many times diffraction limited.

An optical path length of the resonant light 570 may be small, such as less than 2, 5, or 10 mm or in a range between these values, allowing the passively Q-switched laser to output pulses having a pulse width in a range between 1 and 5 ns. For example, the optically pumped gain element may have a thickness between its lateral faces 513 and 514 of 200 microns. The reflections of the resonant light 570 may have an angle of incidence of 45 degrees. A distance along the optical path between each reflective bounce is thus 200/(sin (45 deg.))=283 microns. In the optically pumped gain element 510 depicted in FIG. 5 there are 7 legs of the resonant light 570 optical path and two half length legs. Thus, the length of the optical path of the resonant light 570 in the gain element 510 is 8*283 microns=2.26 mm. There may be a small gap of 100 microns between the second end face 522 of the optically pumped gain element 510 and the first end face 521 of the saturable absorber element. The saturable absorber element may be 300 microns thick. Summing all the parts of the resonant light 570 optical path yields a total length of 2.26+0.1+0.3=2.66 mm. It should be appreciated that the optical path length will be larger than this value due to the optically pumped gain element 510 and saturable absorber element 520 having refractive indices greater than one.

The optical path length of 2.66 mm calculated above is exemplary only. For example, the optically pumped gain element 510 may be thinner, perhaps in a range of 50 to 100 microns or 100 to 200 microns, which would result in a shorter optical path length for the resonant light 570 and more closely spaced reflection points. A thicker gain element, perhaps in the range of 200 to 500 microns or 500 to 1000 microns would result in a longer optical path length and larger spaces between the reflection points. The angle of incidence of the resonant light 570 at the reflection points need not be 45° but may be a larger or smaller angle. The gap between the optically pumped gain element 510 and saturable absorber element 520 may be eliminated. The gain element second face 512 may optically contact the saturable absorber first face 521 eliminating a need of any optical coating on these faces.

The external feedback element need not be the opposed lateral face 513 of the optically pumped gain element 510. Instead, the external feedback element may be a separate optical element situated adjacent the opposed lateral face 513. In this case, the opposed lateral face 513 may remain uncoated and the separate optical element may have a high reflectivity coating for normal incidence light at the second wavelength. The separate optical element may have a plurality of curved depressions that are aligned with the plurality of surface emitting semiconductor gain regions 508a-508f. The curved depressions may provide more concentrated feedback to the surface emitting semiconductor gain regions 508a-508f as compared to a flat surface.

In another embodiment, the external feedback element may be a second surface emitting semiconductor gain element 602 as depicted in FIG. 6. The second surface emitting semiconductor gain element 602 may have a plurality of second surface emitting semiconductor gain regions 608a-608f. The second surface emitting semiconductor gain regions 608a-608f may be aligned with the first semiconductor gain regions 508a-508f. Each pair of plurality of corresponding surface emitting semiconductor gain regions, i.e. 508a/608a, 508b/608b, . . . 508f/608f may form a VECSEL having a circulating pump beam 550. As described previously in regard to FIG. 5, the optically pumped gain element 510 is positioned within the plurality of circulating pump beams 550 and the passively Q-switched laser 600 may emit a series of pulses in an output beam 560. An advantage of the embodiment depicted in FIG. 6 is that more surface emitting semiconductor gain regions can pump the passively Q-switched laser offering the potential for higher average output powers.

While the optically pumped gain element 510 has been described as a parallelopiped having four rectangular faces and two faces being non-rectangular parallelopipeds, the shape of the optically pumped gain element 510 is not so limited. In some embodiments, the optically pumped gain element 510 may be a rectangular parallelopiped and outcoupling of Q-switched light from the gain element may be achieved by optically contacting a prism or some other optical element having an equal or similar refractive index to a face of the optically pumped gain element.

As disclosed above, the optically pumped gain element may be composed of a gain material having neodymium ions doped in a crystalline or glass matrix. The neodymium ions have multiple possible laser transitions. There may be a low gain laser transition and a high gain laser transition. In particular, there are laser transitions that emit light at wavelengths of 1061 and 1064 nm and 1319 and 1338 nm. The wavelengths near 1.06 microns may be characterized as corresponding to high gain laser transitions and the wavelengths near 1.3 microns may be characterized as corresponding to low gain laser transitions. The transitions emitting light near 1.3 microns produce light at an eye-safe wavelength, whereas the transitions emitting light near 1.06 microns do not. The transitions near 1.06 microns have higher gain than those at near 1.3 microns. If eye-safe operation of the passively Q-switched laser is desired, a Q-switched lasing wavelength must be generated by the low gain laser transition. This requires the Q-switch laser resonator being arranged to suppress lasing near 1.06 microns. To suppress 1.06 micron lasing, the resonator must have higher losses for wavelengths near 1.06 microns as compared to 1.3 microns. Higher losses at 1.06 microns may be achieved in a number of ways including, but not limited to, coating the resonator end mirrors so they have lower reflectivity at 1.06 microns than 1.3 microns or adding an intracavity wavelength filter to absorb or deflect outside of the resonator 1.06 micron light. Also, refraction at an obliquely angled surface can result in the resonator being aligned for the low gain laser transition and not aligned for the high gain laser transition. This arrangement dramatically increases the losses for the high gain laser transition promoting lasing on the low gain laser transition.

It should be appreciated that the output power, output wavelength, pulse energy, pulse frequency, and pulse width of any of the embodiments described herein of a passively Q-switched laser can be varied depending on the application. For example, the output power may be in a range of between approximately 10 to 100 mW, 100 mW to 1 W, or 1 W to 10 W. The output wavelength may vary in a range between approximately 1000 to 1200 nm, 1200 to 1400 nm, 1400 to 1600 nm, 1600 to 1800 nm, 1800 to 2000 nm, or 2000 to 2200 nm depending on the lasing ions, the host matrix, and the Q-switched resonator arrangement. The pulse energy may be in a range between approximately 100 nJ to 1 μJ, 1 to 10 μJ, 10 to 100 μJ, 100 μJ to 1 mJ, or 1 to 10 mJ. The pulse frequency may be in a range between 100 Hz to 1 kHz, 1 kHz to 10 kHz, 10 to 100 kHz, 100 kHz to 1 MHz, or 1 to 10 MHz. The passively Q-switched laser may also operate on a single shot basis only outputting an output pulse in response to a user's input signal. The pulse width may in a range of approximately 100 ps to 1 ns, 1 to 10 ns, or 10 to 100 ns depending on resonator parameters such as resonator length and a small signal absorption level in the saturable absorber element.

Any of the laser systems and control methods described herein may be used in a laser ranging system. The ranging system may include the laser and a photodetector responsive to the emitted laser wavelength of the passively Q-switched laser. A control unit may measure an elapsed time between emission of an output pulse and detection of the output pulse reflected from a target to determine a distance between the laser ranging system and the target.

An advantage of any of the embodiments described herein is that the passively Q-switched laser may be able to operate over a broad temperature range without actively controlling a temperature of the various elements in the passively Q-switched laser. For example, the passively Q-switched laser may be able to operate over a temperature range of 25 C, 50 C, 75 C, 100 C or more without active temperature control. This feature stems from the intracavity pumping arrangement, which does not require the pump beam wavelength to match an absorption feature in the optically pumped gain element. The single pass absorption of the pump beam in the optically pumped gain element may be small, for example, less than 0.5%, 1%, 2%, 5%, 10%, 20% or any range between these values. Such low absorption values would result in poor laser efficiency if not for use of intracavity pumping. As a result of this large operating temperature window, in some applications no thermoelectric cooler or heater is required to control the temperature of the passively Q-switched laser or any element within the passively Q-switched laser.

Embodiments described herein include a method of pumping a passively Q-switched laser. The method includes positioning an optically pumped gain element of the passively Q-switched laser in an extended cavity of a vertical extended cavity surface emitting laser having a plurality of electrically pumped surface emitting semiconductor gain regions. A current is applied to the plurality of electrically pumped surface emitting semiconductor gain regions causing the vertical extended cavity surface emitting laser to lase generating a circulating optical pump beam at a second wavelength in the extended cavity. A portion of the circulating optical pump beam of the lasing vertical extended cavity surface emitting laser is absorbed in the gain element. The absorbed portion of the circulating optical pump beam of the lasing vertical extended cavity surface emitting laser causes the passively Q-switched laser to lase, emitting a series of output pulses at a first wavelength.

Although only a few embodiments of the invention have been described in detail, it should be appreciated that the invention may be implemented in many other forms without departing from the spirit or scope of the invention. The invention has been described primarily as a passively Q-switched laser that may be applied to laser ranging applications, but the invention is not so limited. The laser and control methods described herein may be used in other applications requiring a Q-switched output. For example, the Q-switched laser could be used in spectroscopy or material processing applications. The laser wavelength is not limited to approximately 1.3 microns but may be between approximately 0.9-2.2 microns by using different materials for the quantum well region, optically pumped gain element, and the saturable absorber. High-power lasers and laser arrays have been described as having multiple surface emitting semiconductor gain regions on a common substrate, but this is not a requirement. Semiconductor dies having a single gain region may be used in systems having multiple surface emitting semiconductor gain regions. Also, the saturable absorber has been described as being outside of the VECSEL extended cavity, but it may be possible to position the saturable absorber within the VECSEL extended cavity. The external mirror of the VECSEL cavity need not be on a surface of the saturable absorber but may be on a separate optical element, such as a glass mirror. The saturable absorber need not be a vanadium doped yttrium aluminum garnet (YAG) crystal but may be a different dopant in a different host, such as but not limited to Cr:YAG, or alternatively a semiconductor saturable absorber mirror (SESAM). The semiconductor gain region need not be a surface emitting gain region, but in alternative embodiments may be an edge emitting gain region having an extended cavity. As described the surface emitting semiconductor gain region is preferably electrically pumped, although in some embodiments optical pumping may be used. Therefore, the present embodiments should be considered illustrative and not restrictive, and the invention is not to be limited to the details given herein.

1. A variable flow nipple for a nursing bottle dispenser, comprising:
a nipple having a top nipple portion which extends to an intermediate concaved section which extends to a lower dome-shaped body and integrally to a flange, the flange of the nipple used for holding the nipple to the nursing bottle by a collar;
said nipple having a first opening slit having a first length of a short dimension, a second opening slit having a second length of a greater dimension than said first opening slit, said first and second opening slits being radially disposed around the top nipple portion and being spaced apart from an apex of the nipple, the first opening slit and the second opening slit being approximately opposed diametrically upon the nipple, and arranged downwardly upon the nipple from its apex, said nipple having an opened bottom provided at the flange with the nipple having a hollow body through which a liquid may pass from the open bottom through the body and out of at least that opening slit provided downwardly of the nipple when applied to the mouth of a nursing infant;
said opening slits are orally activated to allow liquid to flow at a desired rate when pressure is applied to the nipple portion, and the lengths of each opening slit provided upon said nipple allowing for variable flow rates from said nipple, wherein the liquid flowing from the first opening slit is at a slower rate than the liquid flowing from the second opening slit when the nursing bottle is applied for feeding of an infant, and wherein the approximately diametrically opposed first and second opening slits of different direction are adapted and configured to permit the nipple to be rotated to orient either of the first or second opening slits downwardly in a mouth of an infant to control the flow of liquid at a desired rate.

2. The variable flow nipple for a nursing bottle dispenser of claim 1, wherein there are a pair of parallel arranged first opening slits having the same short length provided through one side of the nipple, and a pair of second opening slits of a longer length and parallel arranged though the opposite side of said nipple, said pair of first opening slits being opposed diametrically from the second pair of slits on said nipple, in order to control the rate of flow of formula from the nursing bottle during feeding of an infant.

3. The variable flow nipple for a nursing bottle dispenser of claim 1, wherein there are three parallel arranged first opening slits having a short length provided through one side of the nipple, and three second opening slits of a longer length and parallel arranged through the opposite side of said nipple, wherein said three parallel arranged first opening slits being opposed diametrically from the three second opening slits upon the said nipple, in order to control the rate of flow of formula from the nursing bottle during feeding of an infant.

4. The variable flow nipple for a nursing bottle dispenser of claim 1, wherein said nursing bottle is formed as a vented container to vent the interior of the bottle to atmosphere during feeding of the infant.

5. The variable flow nipple for a nursing bottle dispenser of claim 1, wherein there are more than three opening slits of the first length and more than three opening slits of the second length formed in said nipple.

6. The variable flow nipple for a nursing bottle dispenser of claim 1, and including a central opening provided at the apex of the nipple, and said central opening and the first and second opening slits are orally activated to allow liquid to flow at a desired rate when pressure is applied to the top nipple portion, and the first and second lengths of the opening slits being different from each other, to allow for the variable flow rates from said nipple at a controlled rate during an infant feeding session.

7. The variable flow nipple for a nursing bottle dispenser of claim 1, wherein the first opening slit provided through the nipple when located downwardly within the mouth of an infant providing for a lesser quantity of liquid being delivered from the nursing bottle to the infant during a feeding, and the second and longer opening slit being located downwardly within the mouth of an infant during feeding providing for a greater quantity of liquid being delivered from the container to the infant during a feeding.

8. The variable flow nipple for a nursing bottle dispenser of claim 6, wherein the central opening comprises a circular aperture.

9. The variable flow nipple for a nursing bottle dispenser of claim 6, bottle wherein said central aperture comprises a pair of cross slits formed at the apex of the nipple.

10. The to the variable flow nipple for a nursing bottle dispenser of claim 9 , wherein the cross cut slits are cut upon a tangent.

11. The dispenser of claim 9, wherein a cross cut slit is cut upon a tangent.

12. The variable flow nipple for a nursing bottle dispenser of claim 9, wherein the openings are provided cross shaped.

13. (canceled)

14. The variable flow nipple for a nursing bottle dispenser of claim 1, wherein indicia is applied to one of the nipple and nursing bottle identifying a full flow of fluid from the longest slit during an infant feeding, and indicia provided in alignment with the shortest slit opening in the nipple identifying the potential for obtaining a lowest flow of formula from the nipple and its nursing bottle during usage.

15. The variable flow nipple for a nursing bottle dispenser of claim 1, and including reinforcing ribs provided within the interior of the nipple along its height to structurally strengthen the nipple against collapse during the feeding of an infant during usage of the nursing bottle.

16. The variable flow nipple for a nursing bottle dispenser of claim 1, and there being at least one further slit of intermediate length between the first opening slit and the second opening slit, arranged at approximately 90 degrees by position radially from said first and second opening slits, in order to provide for an intermediate flow rate of liquid from the nursing bottle when feeding of an infant.

17. The variable flow nipple for a nursing bottle dispenser of claim 1, wherein the first opening slit having a first length of a short dimension being in the range of approximately 0.4 mm to 0.6 mm, and the second opening slit having a second length of a greater dimension having a length of approximately at least 1.2 mm in length.

18. The variable flow nipple for a nursing bottle dispenser of claim 16, wherein the first opening slit being of a length within the range of 0.4 mm to 0.6 mm, the slit of intermediate length having a length of approximately 0.8 mm to 1 mm in length, and the second opening slit of greater dimension having a length of at least 1.2 mm or longer.
